(19) United States
(12) Patent Application Publication
(10) Pub. No.: US 2016/0064550 A1
(43) Pub. Date: Mar. 3, 2016

(54) INSULATED GATE TYPE SWITCHING DEVICE

(71) Applicant: Toyota Jidosha Kabushiki Kaisha, Toyota-shi Aichi-ken (JP)

(72) Inventors: Masahiro Sugimoto, Toyota-shi Aichi-ken (JP); Katsuhiro Kutsuki, Nagakute-shi Aichi-ken (JP); Sachiko Aoi, Nagakute-shi Aichi-ken (JP); Yukihiko Watanabe, Nagakute-shi Aichi-ken (JP); Yasuhiro Ebihara, Nisshin-shi Aichi-ken (JP)

(21) Appl. No.: 14/831,177

(22) Filed: Aug. 20, 2015

(30) Foreign Application Priority Data
Sep. 3, 2014 (JP) 2014-178896

(51) Int. Cl. H01L 29/78; H01L 29/10; H01L 29/08; H01L 29/739

(52) U.S. Cl. CPC H01L 29/7813; H01L 29/7397; H01L 29/1095; H01L 29/0865; H01L 29/0882

(57) ABSTRACT

An insulated gate type switching device includes: a first region being of a first conductivity type; a body region being of a second conductivity type and in contact with the first region; a second region being of the first conductivity type and separated from the first region by the body region; an insulating film being in contact with the first region, the body region and the second region; and a gate electrode facing the body region via the insulating film. The body region includes a first body region and a second body region. The first body region has a theoretical threshold level Vth larger than that of the second body region.

### CROSS-REFERENCE TO RELATED APPLICATION

This application claims priority to Japanese Patent Application No. 2014-178896 filed on Sep. 3, 2014, the contents of which are hereby incorporated by reference into the present application.

### TECHNICAL FIELD

A technology disclosed herein relates to an insulated gate type switching device.

### BACKGROUND ART

Japanese Patent Application Publication No. 2009-158788 discloses a MOSFET.

The application of a voltage equal to or higher than a threshold level to a gate electrode forms a channel in a body region, so that the MOSFET is turned on.

### BRIEF SUMMARY

A gate threshold level of an insulated gate type switching device can be controlled by structures and materials of a body region, a gate insulating film, and a gate electrode. The gate threshold level can be made higher by making it difficult for a channel to be formed in the body region. On the other hand, making it difficult for the channel to be formed in the body region raises resistance of the channel. For this reason, there has conventionally been such a problem that making the gate threshold level higher raises the channel resistance. In order to solve the problem, the present specification provides an insulated gate type switching device having a high gate threshold level and a low channel resistance.

An insulated gate type switching device disclosed herein comprises: a first region being of a first conductivity type; a body region being of a second conductivity type and in contact with the first region; a second region being of the first conductivity type and separated from the first region by the body region; an insulating film being in contact with the first region, the body region and the second region; and a gate electrode facing the body region via the insulating film. The body region comprises a first body region and a second body region. In a region being in contact with the insulating film, the first body region is in contact with the first region and separated from the second region by the second body region. In the region being in contact with the insulating film, the second body region is in contact with the second region and separated from the first region by the first body region. The first body region has a theoretical threshold level Vth larger than that of the second body region. The theoretical threshold level Vth is calculated by a formula “Vth=φMS−QB/Cox+2φFB”. The value φMS is a value obtained by subtracting a work function of the gate electrode from a work function of the body region. The value Cox is a capacitance per unit area between the body region and the gate electrode. The value φFB is calculated by a formula “φFB=kT ln(NA/ni)”. The value k is a Boltzmann constant. The value T is a temperature of the body region. The value NA is a concentration of impurities in the body region. The value ni is a concentration of carriers in an intrinsic semiconductor made of a material of the body region. The value QB is calculated by a formula “QB=qNAxd”. The value q is an elementary charge of an electron. The value xd is calculated by a following formula, in which the values is a dielectric constant of the material of the insulating film.

$$xd = {( \frac{4 ɛ kTln ( \frac{NA}{ni} )}{{q}^{2} NA} )}^{\frac{1}{2}}$$

It should be noted that one of the first conductivity type and the second conductivity type may be an n type and the other of the first conductivity type and the second conductivity type may be a p type. A unit of the value φMS is eV. The value φMS is a value that is determined by a material of the body region, a concentration of impurities in the body region, and a material of the gate electrode. If the first body region and the second body region are identical in these materials and in concentrations of impurities to each other, the first body region and the second body region are equal in value φMS to each other. A unit of the temperature T is K. In calculating the theoretical threshold value Vth, let it be assumed that the first body region and the second body region are equal in temperature T to each other. The theoretical threshold level Vth may be calculated with the temperature T as a fixed value indicating an ordinary temperature (e.g. 298 K). A unit of the concentration ni of carriers is atoms/cm³. If the first body region and the second body region are made of the same material as each other, the first body region and the second body region are equal in value ni to each other. A unit of the concentration NA of impurities is atoms/cm³. A unit of the dielectric constant ∈ is F/m. The value xd is a value that is determined by the concentration NA of impurities in the body region, provided that the first body region and the second body region are made of the same material as each other. In this case, the value QB is a value that is determined by the concentration NA of impurities in the body region. The value φFB is a value that is determined by the concentration NA of impurities and the intrinsic carrier concentration ni. The value φFB is a value that is determined by the concentration NA of impurities in the body region, provided that the first body region and the second body region are made of the same material as each other. A unit of the capacitance Cox is F/m². The value capacitance Cox is a value that is determined by the mathematical formula Cox=∈/d from the thickness d and the dielectric constant ∈ of the gate insulating film.

In this insulated gate type switching device, raising a gate voltage to a potential substantially equal to the theoretical threshold level of the second body region forms a channel in the second body region. Since the theoretical threshold level of the first body region is higher than the theoretical threshold level of the second body region, the insulated gate type switching device is not turned on at this stage. Further raising the gate voltage to a potential substantially equal to the theoretical threshold level of the first body region forms a channel in the first body region. At this stage, the first region and the second region are connected to each other via the channel, so that the insulated gate type switching device is turned on. Therefore, a gate threshold level of this insulated gate type switching device is determined on the basis of the high theoretical threshold level of the first body region. Further, a rise in the gate voltage to the theoretical threshold level of the first body region increases amount of mobile electrons in the channel formed in the second body region. For this reason, the resistance of the channel that is formed in the second body region is low. This allows a reduction in the resistance of the channel. In this way, the structure of this insulated gate type switching device can achieve a high gate threshold level and a low channel resistance.

### BRIEF DESCRIPTION OF DRAWINGS

FIG. 1 is a longitudinal sectional view of a MOSFET 10 of Embodiment 1.

FIG. 2 is a longitudinal sectional view of a MOSFET 200 of Embodiment 2.

FIG. 3 is a longitudinal sectional view of a MOSFET 300 of Embodiment 3.

FIG. 4 is a longitudinal sectional view of a MOSFET 400 of Embodiment 4.

FIG. 5 is a longitudinal sectional view of a MOSFET 500 of Embodiment 5.

FIG. 6 is a longitudinal sectional view of a MOSFET 600 of Embodiment 6.

FIG. 7 is a longitudinal sectional view of a trench gate type MOSFET.

### DETAILED DESCRIPTION

### Embodiment 1

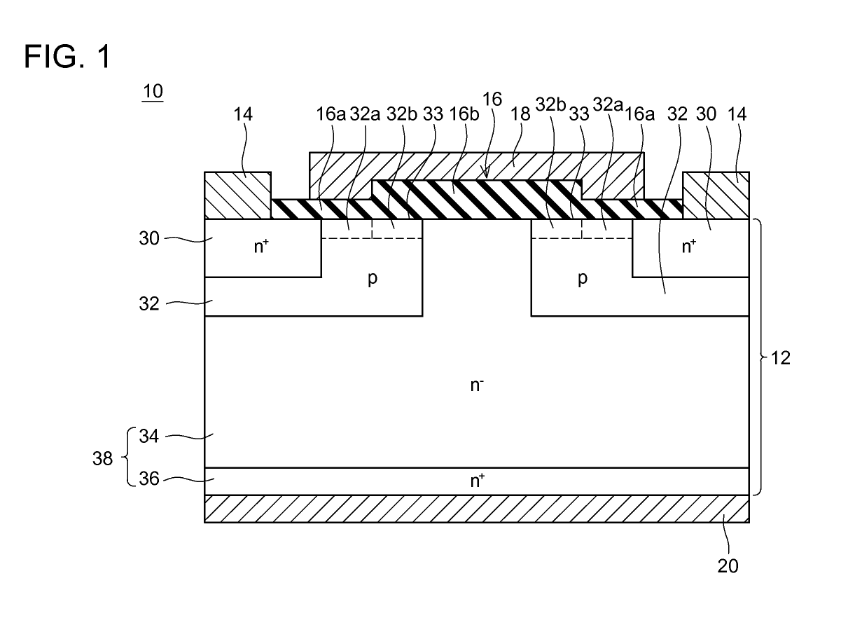

FIG. 1 shows a MOSFET 10. The MOSFET 10 includes a semiconductor substrate 12. The semiconductor substrate 12 is made of SiC.

A plurality of source electrodes 14 is formed on an upper surface of the semiconductor substrate 12. The source electrodes 14 are formed with a clearance between each other. Each of the source electrodes 14 is in contact with the upper surface of the semiconductor substrate 12.

A gate insulating film 16 is formed on the upper surface of the semiconductor substrate 12. The gate insulating film 16 is formed between two source electrodes 14. The source electrodes 14 are in contact with the upper surface of the semiconductor substrate 12. The gate insulating film 16 is made of SiO₂. The gate insulating film 16 includes a thin film portion 16a and a thick film portion 16b. The thin film portion 16a is small in thickness, and the thick film portion 16b is large in thickness. The thick film portion 16b is formed in an intermediate position between the two source electrodes 14. The thin film portion 16a is formed between the thick film portion 16b and the source electrodes 14.

A gate electrode 18 is formed on an upper surface of the gate insulating film 16. The gate electrode 18 is made of polysilicon. The gate electrode 18 is formed in a position with a clearance from each of the source electrodes 14. The gate electrode 18 is formed in an area extending from an upper surface of the thick film portion 16b to an upper surface of the thin film portion 16a. That is, the gate electrode 18 is in contact with the upper surface of the thick film portion 16b and the upper surface of the thin film portion 16a on both sides of the thick film portion 16b. The gate electrode 18 faces after-mentioned source regions 30 to be described later, source-side body regions 32a, drain-side body regions 32b, and a drift region 34 via the gate insulating film 16.

A drain electrode 20 is formed on a lower surface of the semiconductor substrate 12. The drain electrode 20 is in contact with substantially the whole area of the lower surface of the semiconductor substrate 12.

A plurality of source regions 30 is formed inside the semiconductor substrate 12. Each of the source regions 30 is an n-type semiconductor region. Each of the source regions 30 is formed in such an area as to be exposed at the upper surface of the semiconductor substrate 12. Each of the source regions 30 is formed under the corresponding source electrode 14. Each of the source regions 30 is connected to the corresponding source electrodes 14. A surface of the source region 30 in a position adjacent to the corresponding source electrode 14 is covered with the gate insulating film 16.

A plurality of body regions 32 is formed inside the semiconductor substrate 12. Each of the body regions 32 is a p-type semiconductor region. Each of the body regions 32 is formed to be in contact with a lower surface and side surface of a source region 30. Each of the body regions 32 is exposed at the upper surface of the semiconductor substrate 12 in a position adjacent to the corresponding source region 30. Each of surfaces 33 of each of the body regions 32 exposed at the upper surface of the semiconductor substrate 12 is covered with the gate insulating film 16. The thick film portion 16b and the thin film portion 16a are formed on each of the surfaces 33. A part of each of the surfaces 33 that is close to the corresponding source region 30 is covered with the thin film portion 16a. A part of each of the surfaces 33 that is far from the corresponding source region 30 is covered with the thick film portion 16b. That is, a part of each of the body regions 32 exposed at the corresponding surface 33 includes a source-side body region 32a covered with the thin film portion 16a and a drain-side body region 32b (i.e. parts of the body regions 32 that are close to a drain region 38 to be described later) covered with the thick film portion 16b.

A drain region 38 is formed inside the semiconductor substrate 12. The drain region 38 is an n-type semiconductor region. The drain region 38 includes a drift region 34 and a contact region 36.

The drift region 34 is an n-type semiconductor region containing n-type impurities at low concentration. The drift region 34 is formed to be in contact with lower surfaces and side surfaces of the body regions 32. The drift region 34 is exposed at the upper surface of the semiconductor substrate 12 in a position between the two body regions 32. A surface of the drift region 34 exposed at the upper surface of the semiconductor substrate 12 is covered with the thick film portion 16b of the gate insulating film 16. The drift region 34 is separated from the source regions 30 by the body regions 32, respectively. The contact region 36 is an n-type semiconductor region containing n-type impurities at high concentration. The contact region 36 is formed to be in contact with a lower surface of the drift region 34. The contact region 36 is exposed at the lower surface of the semiconductor substrate 12. The contact region 36 is connected to the drain electrode 20.

Each of the source-side body regions 32a described above is in contact with corresponding one of the source regions 30 in a position being in contact with the gate insulating film 16 (i.e. the upper surface of the semiconductor substrate 12). Further, each of the source-side body regions 32a is separated from the drift region 34 by the corresponding drain-side body region 32b in the position being in contact with the gate insulating film 16. Each of the drain-side body regions 32b is in contact with the drift region 34 in the position being in contact with the gate insulating film 16. Further, each of the drain-side body regions 32b is separated from the corresponding source region 30 by the corresponding source-side body region 32a in the position being in contact with the gate insulating film 16.

The following discusses a theoretical threshold level Vth of the source-side body regions 32a and that of the drain-side body regions 32b. The theoretical threshold level Vth is the minimum gate voltage that is needed to form a channel in each body region. As mentioned above, the theoretical threshold level Vth can be calculated by the mathematical formula: Vth=φMS−QB/Cox+2φFB (where Cox=∈/d).

In Embodiment 1, a semiconductor material of the source-side body regions 32a and a semiconductor material of the drain-side body regions 32b are both SiC. Therefore, the source-side body regions 32a and the drain-side body regions 32b are equal in their values ni (i.e., ni being a concentration of carriers in an intrinsic semiconductor made of a material of the body region) to each other. Further, a concentration NA of p-type impurities in the source-side body regions 32a and a concentration NA of p-type impurities in the drain-side body regions 32b are equal to each other. Therefore, the source-side body regions 32a and the drain-side body regions 32b are equal in their values φFB to each other.

Further, a material of the gate insulating film 16 (i.e. the thin film portion 16a) on the source-side body regions 32a and a material of the gate insulating film 16 (i.e. the thick film portion 16b) on the drain-side body regions 32b are both SiO₂. For this reason, a dielectric constant ∈ of the thick film portion 16b is equal to a dielectric constant ∈ of the thin film portion 16a. Furthermore, as mentioned above, the source-side body regions 32a and the drain-side body regions 32b are equal in their values ni and NA to each other. Therefore, the source-side body regions 32a and the drain-side body regions 32b are equal in their values QB to each other.

Further, a material of the gate electrode 18 above the source-side body regions 32a and a material of the gate electrode 18 above the drain-side body regions 32b are both polysilicon. Therefore, these materials have the same work function. Further, as mentioned above, the semiconductor material of the source-side body regions 32a and the semiconductor material of the drain-side body regions 32b are the same. Therefore, these materials have the same work function. For this reason, the source-side body regions 32a and the drain-side body regions 32b are equal in their values φMS to each other.

Further, a thickness of the gate insulating film 16 (i.e. the thin film portion 16a) on the source-side body regions 32a is smaller than a thickness of the gate insulating film 16 (i.e. the thick film portion 16b) on the drain-side body regions 32b. Further, as mentioned above, the dielectric constant ∈ of the thin film portion 16a is equal to the dielectric constant ∈ of the thick film portion 16b. Therefore, a value Cox of the source-side body regions 32a is larger than a value Cox of the drain-side body regions 32b.

For this reason, the theoretical threshold level Vth of the source-side body regions 32a is smaller than the theoretical threshold level Vth of the drain-side body regions 32b.

The following describes how the MOSFET 10 operates. When the MOSFET 10 is in use, a higher voltage is applied to the drain electrode 20 than to the source electrodes 14. In a case where a potential of the gate electrode 18 (such a potential being hereinafter referred to as “gate potential”) is low, no channel is formed in the source-side body regions 32a and the drain-side body regions 32b, so that the MOSFET 10 is in an off state. Raising the gate potential to a potential substantially equal to the theoretical threshold level Vth of the source-side body regions 32a forms a channel in the source-side body regions 32a near the gate insulating film 16. At this stage, however, no channel is formed in the drain-side body regions 32b, as the gate potential is lower than the theoretical threshold level Vth of the drain-side body regions 32b. For this reason, no current flows through the MOSFET 10. Further raising the gate potential increases a width of the channel in the source-side body regions 32a. For this reason, along with the rise in the gate potential, a resistance of the channel in the source-side body regions 32a is decreased. Raising the gate potential to a potential substantially equal to the theoretical threshold level Vth of the drain-side body regions 32b forms a channel in the drain-side body regions 32b near the gate insulating film 16. The formation of the channel in the drain-side body regions 32b connects the source regions 30 and the drift region 34 to each other via the channel in the source-side body regions 32a and the channel in the drain-side body regions 32b. This causes electrons to flow from the source regions 30 to the contact region 36 via the channel in the source-side body regions 32a, the channel in the drain-side body regions 32b, and the drift region 34. That is, a current flows from the contact region 36 to the source regions 30. This causes the MOSFET 10 to be turned on.

As described above, the MOSFET 10 is turned on when the gate potential has risen to a potential substantially equal to the theoretical threshold level of the drain-side body regions 32b, which is higher than the theoretical threshold level of the source-side body regions 32a. That is, a threshold level of the MOSFET 10 as a whole is determined by the higher theoretical threshold level of the drain-side body regions 32b. By providing the drain-side body regions 32b having the higher theoretical threshold level in the body regions 32, the threshold level of the MOSFET 10 can be made higher. Further, as mentioned above, the channel resistance of the source-side body regions 32a is low at the stage where the MOSFET 10 has been turned on. This reduces the resistance of the channels in the MOSFET 10. As described above, by providing the source-side body regions 32a having the lower theoretical threshold level in the body regions 32, the channel resistance can be made lower than it is in a case where the theoretical threshold level of the body regions 32 as a whole is high. In this way, the MOSFET 10 of Embodiment 1 can achieve a high threshold level and a low channel resistance.

Further, lowering the gate potential and turning off the MOSFET 10 causes a depletion layer to extend in the drift region 34 from a p-n junction at a boundary between the body regions 32 and the drift region 34. For this reason, turning off the MOSFET 10 forms an electric field peak at the boundary between the body regions 32 and the drift region 34. In the MOSFET 10, the thick film portion 16b is formed on the drain-side body regions 32b. For this reason, the thick film portion 16b is formed in a position being in contact with the boundary between the body regions 32 and the drift region 34. By thus providing the thick film portion 16b in a position where an electric field is easily concentrated, the resistance of the gate insulating film 16 to an electric field can be improved.

In Embodiment 1 described above, the gate insulating film 16 on the source-side body regions 32a is thin, and the gate insulating film 16 of the drain-side body regions 32b is thick. Alternatively, the gate insulating film 16 on the source-side body regions 32a may be thick, and the gate insulating film 16 of the drain-side body regions 32b may be thin. This configuration, too, can achieve a high gate threshold level and a low channel resistance. In this case, however, the resistance to an electric field is low, as a thin gate insulating film 16 is formed above the p-n junction, where an electric field is easily concentrated.

### Embodiment 2

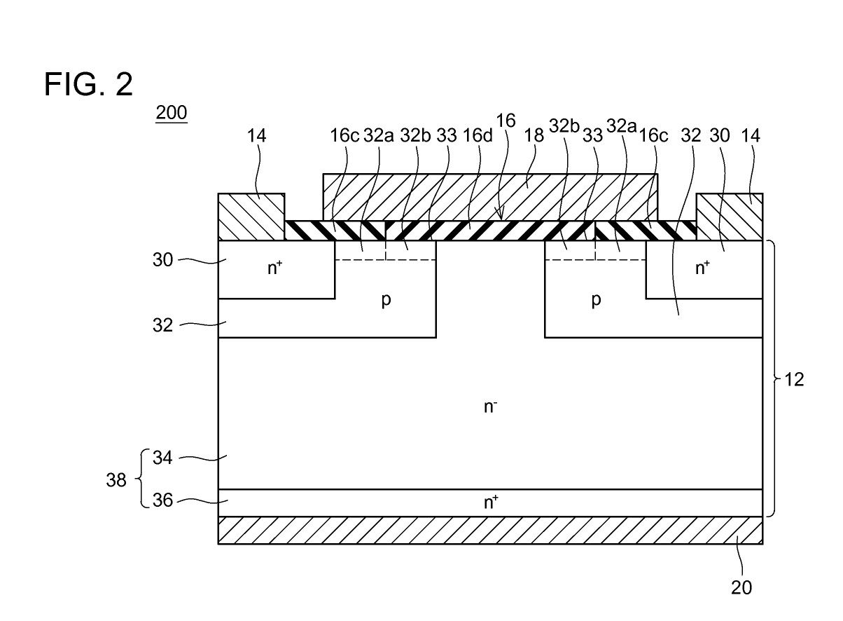

FIG. 2 shows a MOSFET 200 of Embodiment 2. The MOSFET 200 of Embodiment 2 is different in its configuration of the gate insulating film 16 from the MOSFET 10 of Embodiment 1, and is identical in other configurations to the MOSFET 10 of Embodiment 1. In the MOSFET 200 of Embodiment 2, the thickness of the gate insulating film 16 is constant. Further, in the MOSFET 200 of Embodiment 2, the gate insulating film 16 includes an insulating film 16c made of HfO₂ and an insulating film 16d made of SiO₂. The insulating film 16c (i.e. HfO₂) has a relative dielectric constant ∈r of about 30, and the insulating film 16d (i.e. SiO₂) has a relative dielectric constant ∈r of about 3.9. Therefore, a dielectric constant ∈ (=∈ᵣ∈₀, where ∈₀ is the dielectric constant of a vacuum) of the insulating film 16c is larger than a dielectric constant ∈ (=∈ᵣ∈₀) of the insulating film 16d. The insulating film 16c is formed in an area corresponding to the thin film portion 16a of Embodiment 1, and the insulating film 16d is formed in an area corresponding to the thick film portion 16b of Embodiment 1. That is, the insulating film 16c covers surfaces of the source-side body regions 32a and the source regions 30. The insulating film 16d covers surfaces of the drain-side body regions 32b and the drift region 34. The gate electrode 18 is formed in an area extending from an upper surface of the insulating film 16c to an upper surface of the insulating film 16d.

The following discusses the theoretical threshold level Vth of the source-side body regions 32a and that of the drain-side body regions 32b. For the same reasons as those noted in Embodiment 1, the source-side body regions 32a and the drain-side body regions 32b are equal in φMS and φFB to each other.

A thickness of the insulating film 16c on the source-side body regions 32a is equal to a thickness of the insulating film 16d on the drain-side body regions 32b. Further, the dielectric constant ∈ of the insulating film 16c on the source-side body regions 32a is higher than the dielectric constant ∈ of the insulating film 16d on the drain-side body regions 32b. Therefore, the value Cox of the source-side body regions 32a is larger than the value Cox of the drain-side body regions 32b. That is, a value QB/Cox of the source-side body regions 32a is smaller than a value QB/Cox of the drain-side body regions 32b.

Further, the source-side body regions 32a and the drain-side body regions 32b are made of the same material as each other. For this reason, the source-side body regions 32a and the drain-side body regions 32b are equal in values ni and NA to each other. Therefore, the source-side body regions 32a and the drain-side body regions 32b are equal in value QB to each other.

For this reason, the theoretical threshold level Vth of the source-side body regions 32a whose value QB/Cox is small is smaller than theoretical threshold level Vth of the drain-side body regions 32b whose value QB/Cox is large.

In the MOSFET 200, too, the body regions 32 include the source-side body regions 32a whose theoretical threshold level Vth is small and the drain-side body regions 32b whose theoretical threshold level Vth is large. For this reason, the MOSFET 200 has a high gate threshold level and a low channel resistance.

In Embodiment 2 described above, the dielectric constant ∈ of the insulating film 16c on the source-side body regions 32a is high, and the dielectric constant ∈ of the insulating film 16d on the drain-side body regions 32b is low. Alternatively, the dielectric constant ∈ of the gate insulating film 16 on the source-side body regions 32a may be low, and the dielectric constant ∈ of the gate insulating film 16 on the drain-side body regions 32b may be high. This configuration, too, can achieve a high gate threshold level and a low channel resistance.

### Embodiment 3

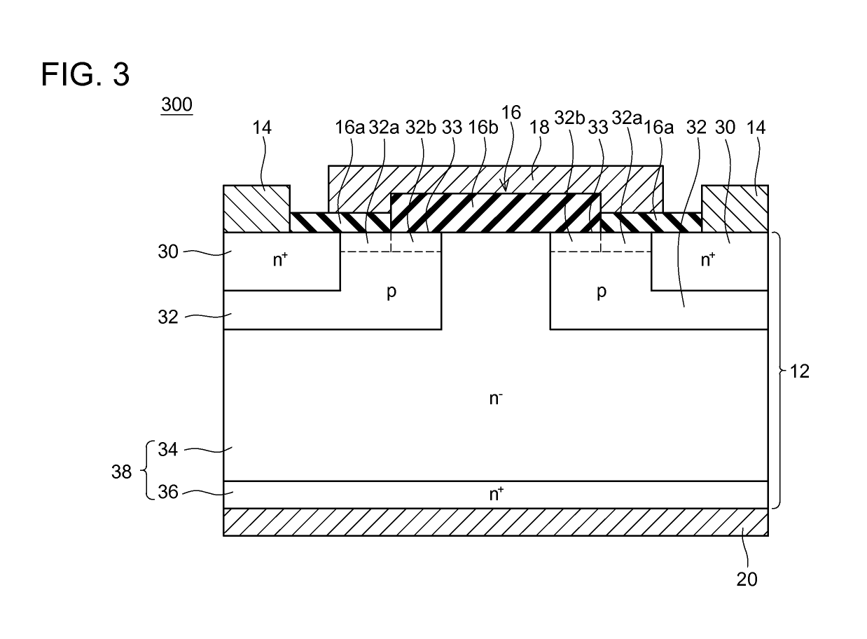

FIG. 3 shows a MOSFET 300 of Embodiment 3. The MOSFET 300 of Embodiment 3 is different in its configuration of the gate insulating film 16 from the MOSFET 10 of Embodiment 1, and is identical in other configurations to the MOSFET of Embodiment 1. In the MOSFET 300 of Embodiment 3, the thin film portion 16a is made of SiO₂, and the thick film portion 16b is made of HfO₂.

The following discusses the theoretical threshold level Vth of the source-side body regions 32a and that of the drain-side body regions 32b. For the same reasons as those noted in Embodiment 1, the source-side body regions 32a and the drain-side body regions 32b are equal in φMS and φFB to each other. Further, for the same reason as that noted in Embodiment 2, the source-side body regions 32a and the drain-side body regions 32b are equal in value QB to each other.

A thickness d1 of the thin film portion 16a on the source-side body regions 32a is smaller than a thickness d2 of the thick film portion 16b on the drain-side body regions 32b. On the other hand, a dielectric constant ∈1 of the thin film portion 16a (i.e. SiO₂) is smaller than a dielectric constant ∈2 of the thick film portion 16b (i.e. HfO₂). In Embodiment 3, the value Cox (=∈1/d1) of the source-side body regions 32a is set to be larger than the value Cox (=∈2/d2) of the drain-side body regions 32b.

For this reason, the theoretical threshold level Vth of the source-side body regions 32a (whose value Cox is large) is smaller than theoretical threshold level Vth of the drain-side body regions 32b (whose value Cox is small).

In the MOSFET 300, too, the body regions 32 include the source-side body regions 32a whose theoretical threshold level Vth is small and the drain-side body regions 32b whose theoretical threshold level Vth is large. For this reason, the MOSFET 300 has a high gate threshold level and a low channel resistance.

### Embodiment 4

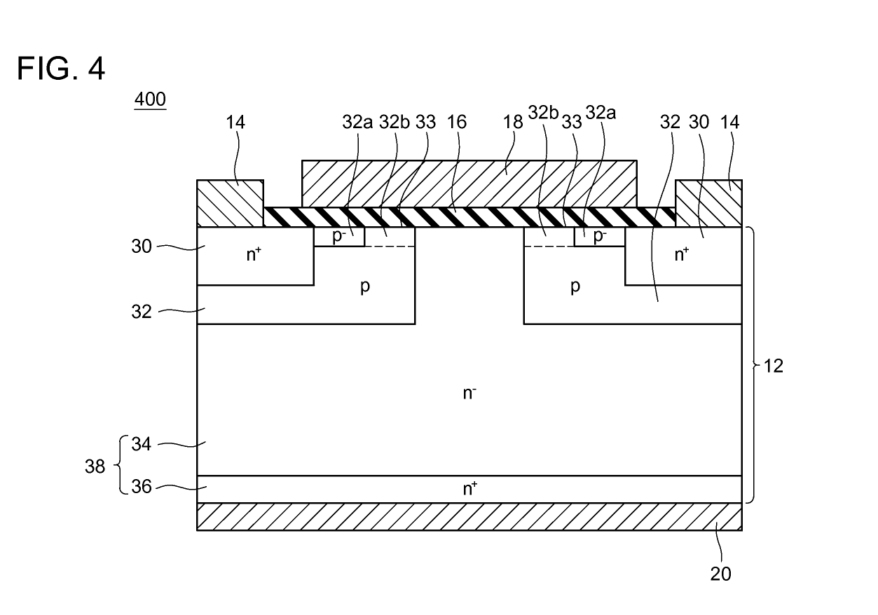

FIG. 4 shows a MOSFET 400 of Embodiment 4. The MOSFET 400 of Embodiment 4 is different in its configuration of the gate insulating film 16 and the body regions 32 from the MOSFET 10 of Embodiment 1, and is identical in other configurations to the MOSFET 10 of Embodiment 1. In the MOSFET 400 of Embodiment 4, the thickness of the gate insulating film 16 is constant. Further, in the MOSFET 400 of Embodiment 4, the concentration of p-type impurities in the source-side body regions 32a is lower than the concentration of p-type impurities in the drain-side body regions 32b.

The following discusses the theoretical threshold level Vth of the source-side body regions 32a and that of the drain-side body regions 32b.

Since the thickness of the gate insulating film 16 is constant and the gate insulating film 16 is made of the same material in any part thereof, values of Cox of the source-side body regions 32a and the drain-side body regions 32b are equal to each other.

Since the source-side body regions 32a and the drain-side body regions 32b are different in their concentration NA of p-type impurities from each other, the source-side body regions 32a and the drain-side body regions 32b are different in values φMS, QB, and φFB from each other. When the concentration NA of p-type impurities in the body regions 32 is small, all of the values φMS, QB, and φFB act in such a direction as to lower the theoretical threshold level Vth.

Therefore, the theoretical threshold level Vth of the source-side body regions 32a (whose concentration NA of p-type impurities is low) is smaller than the theoretical threshold level Vth of the drain-side body regions 32b (whose concentration NA of p-type impurities is large).

In the MOSFET 400, too, the body regions 32 includes the source-side body regions 32a whose theoretical threshold level Vth is small and the drain-side body regions 32b whose theoretical threshold level Vth is large. For this reason, the MOSFET 400 has a high gate threshold level and a low channel resistance.

In Embodiment 4 described above, the concentration of p-type impurities in the source-side body regions 32a is lower than the concentration of p-type impurities in the drain-side body regions 32b. Alternatively, the concentration of p-type impurities in the source-side body regions 32a may be higher than the concentration of p-type impurities in the drain-side body regions 32b. This configuration, too, can achieve a high gate threshold level and a low channel resistance.

### Embodiment 5

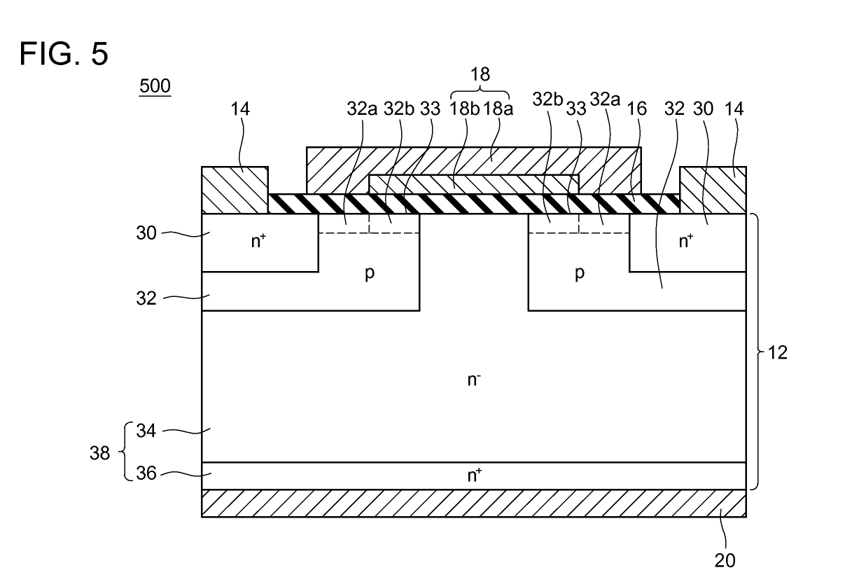

FIG. 5 shows a MOSFET 500 of Embodiment 5. The MOSFET 500 of Embodiment 5 is different in its configuration of the gate insulating film 16 and the gate electrode 18 from the MOSFET 10 of Embodiment 1, and is identical in other configurations to the MOSFET 10 of Embodiment 1. In the MOSFET 500 of Embodiment 5, the thickness of the gate insulating film 16 is constant. Further, in the MOSFET 500 of Embodiment 5, the gate electrode 18 includes a first gate electrode 18a made of TiN and a second gate electrode 18b made of p-type polysilicon. The second gate electrode 18b is formed on a portion of the gate insulating film 16 covering the surfaces of the drain-side body regions 32b and the drift region 34. That is, the second gate electrode 18b is formed above an area where the drain-side body regions 32b and the drift region 34 are exposed at the upper surface of the semiconductor substrate 12. The first gate electrode 18a is formed extending from the upper surface of the gate insulating film 16 to an upper surface of the second gate electrode 18b. The first gate electrode 18a is in contact with the upper surface of a portion of the gate insulating film 16 covering the surfaces of the source-side body regions 32a and the source regions 30. That is, the first gate electrode 18a is in contact with the gate insulating film 16 above an area where the source-side body regions 32a and the source regions 30 are exposed at the upper surface of the semiconductor substrate 12.

The following discusses the theoretical threshold level Vth of the source-side body regions 32a and that of the drain-side body regions 32b. For the same reason as that noted in Embodiment 1, the source-side body regions 32a and the drain-side body regions 32b are equal in value φFB to each other. The thickness and material of the gate insulating film 16 on the source-side body regions 32a are the same as the thickness and material of the gate insulating film 16 on the drain-side body regions 32b. Therefore, the source-side body regions 32a and the drain-side body regions 32b are equal in their values QB and Cox to each other.

Since the source-side body regions 32a and the drain-side body regions 32b are the same in material and concentration of p-type impurities as each other, a work function of the source-side body regions 32a and a work function of the drain-side body regions 32b are equal to each other. In Embodiment 5, since the source-side body regions 32a and the drain-side body regions 32b are both made of p-type SiC, the source-side body regions 32a and the drain-side body regions 32b both have a work function of about −5.7 eV. On the other hand, the first gate electrode 18a (i.e. TiN) has a work function WF1 of about −4.7 eV. The second gate electrode 18b (i.e. p-type polysilicon) has a work function WF2 of about −4.5 eV. That is, the work function WF1 of the first gate electrode 18a is larger than the work function WF2 of the second gate electrode 18b (It should be noted that in the present specification, a work function is said to be large when it has a large absolute value.). The value φMS is a value obtained by subtracting a work function of the body regions 32 from a work function of the gate electrode 18. In the source-side body regions 32a, φMS=WF1−WF0 (=1.0 eV). In the drain-side body regions 32b, φMS=WF2−WF0 (=1.2 eV). That is, the value φMS of the source-side body regions 32a is smaller than the value φMS of the drain-side body regions 32b.

Therefore, the theoretical threshold level Vth of the source-side body regions 32a (where the work function WF1 of the first gate electrode 18a is large) is smaller than the theoretical threshold level Vth of the drain-side body regions 32b (where the work function WF2 of the second gate electrode 18b is small).

In the MOSFET 500, too, the body regions 32 includes the source-side body regions 32a whose theoretical threshold level Vth is small and the drain-side body regions 32b whose theoretical threshold level Vth is large. For this reason, the MOSFET 500 has a high gate threshold level and a low channel resistance.

In Embodiment 5 described above, the work function of the first gate electrode 18a above the source-side body regions 32a is larger than the work function of the second gate electrode 18b above the drain-side body regions 32b. Alternatively, the work function of the first gate electrode 18a above the source-side body regions 32a may be smaller than the work function of the second gate electrode 18b above the drain-side body regions 32b. This configuration, too, can achieve a high gate threshold level and a low channel resistance.

### Embodiment 6

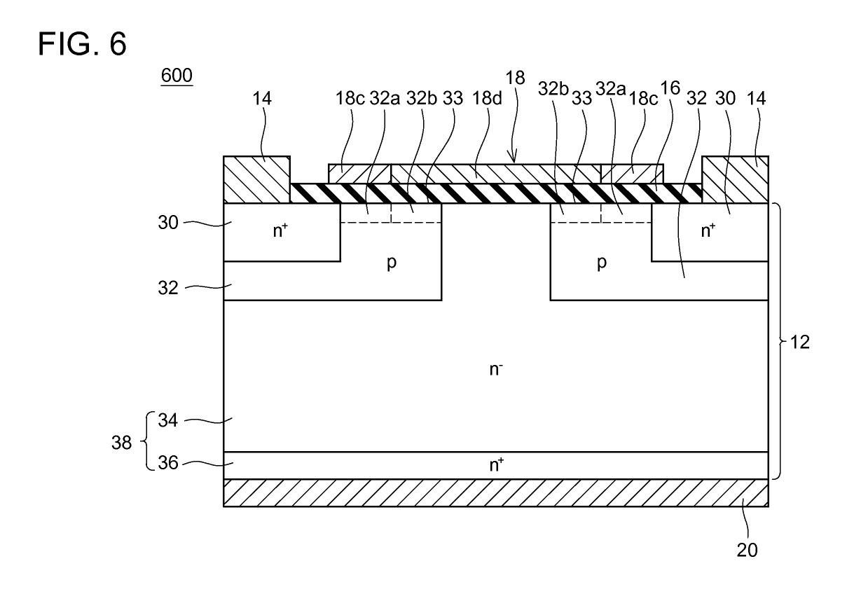

FIG. 6 shows a MOSFET 600 of Embodiment 6. The MOSFET 600 of Embodiment 6 is different in configuration of the gate insulating film 16 and the gate electrode 18 from the MOSFET 10 of Embodiment 1, and is identical in other configurations to the MOSFET 10 of Embodiment 1. In the MOSFET 600 of Embodiment 6, the thickness of the gate insulating film 16 is constant. Further, in the MOSFET 600 of Embodiment 6, the gate electrode 18 is made of n-type polysilicon. The gate electrode 18 includes a first portion 18c doped with n-type impurities at a low concentration and a second portion 18d doped with n-type impurities at a higher concentration than the first portion 18c. The second portion 18d is formed on a portion of the gate insulating film 16 covering the surfaces of the drain-side body regions 32b and the drift region 34. That is, the second portion 18d is formed above an area where the drain-side body regions 32b and the drift region 34 are exposed at the upper surface of the semiconductor substrate 12. The first portion 18c is formed on a portion of the gate insulating film 16 covering the surfaces of the source-side body regions 32a and the source regions 30. That is, the first portion 18c is formed above areas where the source-side body regions 32a and the source regions 30 are exposed at the upper surface of the semiconductor substrate 12.

The following discusses the theoretical threshold level Vth of the source-side body regions 32a and that of the drain-side body regions 32b. For the same reasons as those noted in Embodiment 5, the source-side body regions 32a and the drain-side body regions 32b are equal in values φFB, QB, and Cox to each other.

Since the source-side body regions 32a and the drain-side body regions 32b are the same in material and concentration of p-type impurities as each other, the work function of the source-side body regions 32a and the work function of the drain-side body regions 32b are equal to each other. In Embodiment 6, since the source-side body regions 32a and the drain-side body regions 32b are both made of p-type SiC, the source-side body regions 32a and the drain-side body regions 32b both have a work function of about −5.7 eV. On the other hand, the first portion 18c (i.e. a low centration of n-type polysilicon) of the gate electrode 18 have a work function WF3 of about −3.8 eV. Further, the second portion 18d (i.e. a high centration of n-type polysilicon) of the gate electrode 18 has a work function WF4 of about −3.5 eV. The value φMS is a value obtained by subtracting a work function of the body regions 32 from a work function of the gate electrode 18. In the source-side body regions 32a, φMS=WF3−WF0 (=1.9 eV). In the drain-side body regions 32b, φMS=WF4−WF0 (=2.2 eV). That is, the value φMS of the source-side body regions 32a is smaller than the value φMS of the drain-side body regions 32b.

Therefore, the theoretical threshold level Vth of the source-side body regions 32a (where the gate electrode 18 has a large work function) is smaller than the theoretical threshold level Vth of the drain-side body regions 32b (where the gate electrode 18 has a small work function).

In the MOSFET 600, too, the body regions 32 includes the source-side body regions 32a whose theoretical threshold level Vth is small and the drain-side body regions 32b whose theoretical threshold level Vth is large. For this reason, the MOSFET 600 has a high gate threshold level and a low channel resistance.

In Embodiment 6 described above, the work function of the first portion 18c of gate electrode 18 above the source-side body regions 32a is larger than the work function of the second portion 18d of the gate electrode 18 above the drain-side body regions 32b. Alternatively, the work function of the gate electrode 18 above the source-side body regions 32a may be smaller than the work function of the gate electrode 18 above the drain-side body regions 32b. This configuration, too, can achieve a high gate threshold level and a low channel resistance.

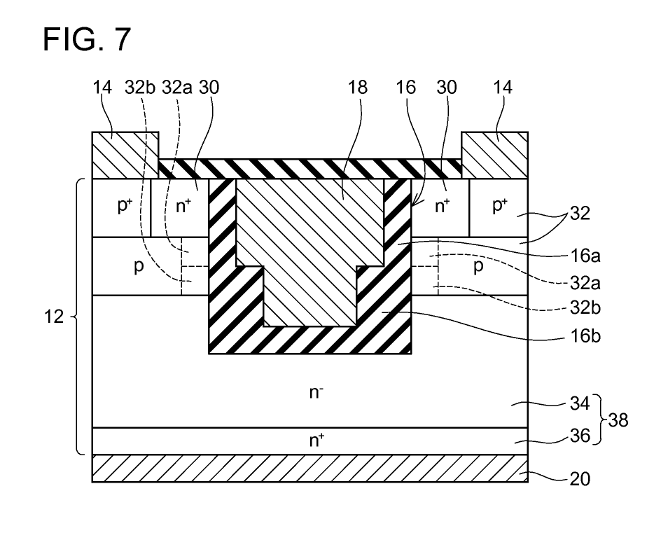

In each of Embodiments 1 to 6 described above, a planar type MOSFET in which the gate insulating film 16 is formed on the semiconductor substrate 12 and the gate electrode 18 is formed above the semiconductor substrate 12 has been described. Alternatively, as shown in FIG. 7, body regions 32a and 32b differing in theoretical threshold level Vth from each other may be formed in each of body regions 32 of a trench type MOSFET. FIG. 7 shows, as an example, a configuration in which a gate insulating film 16 being in contact with the drain-side body regions 32b serves as thick film portions 16b and a gate insulating film 16 being in contact with the source-side body regions 32a serves as thin film portions 16a. In the trench type MOSFET, too, body regions 32a and 32b differing in theoretical threshold level Vth from each other may be formed by employing any of the various methods described in Embodiments 1 to 6 instead of the configuration shown in FIG. 7.

Further, in each of Embodiments 1 to 6 described above, the ratio of the channel length of the source-side body regions 32a to the channel length of the drain-side body regions 32b is one to one (1:1). Alternatively, this ratio can be changed to any ratio.

Further, in each of Embodiments 1 to 6 described above, a MOSFET has been described. Alternatively, the technology of any one of Embodiments 1 to 6 may be employed in an IGBT. An IGBT is obtained by forming a p-type collector region in place of the contact region 36 in any one of Embodiments 1 to 6.

A configuration of an insulated gate type switching device disclosed herein is described below.

In a first example of the insulated gate type switching device disclosed herein, a portion of the insulating film being in contact with the first body region is thicker than a portion of the insulating film being in contact with the second body region. This configuration allows the first body region to have a theoretical threshold level higher than that of the second body region. In this case, the first region may be a drain region, and the second region may be a source region. A high electric field is easily applied to a boundary portion between the drain region and the body region. Therefore, a withstand voltage characteristic of the gate insulting film can be improved by thickening the portion of the insulating film being in contact with the first body region on the side of the drain region.

In a second example of the insulated gate type switching device disclosed herein, a dielectric constant of a portion the insulating film being in contact with the first body region is smaller than a dielectric constant of a portion of the insulating film being in contact with the second body region. This configuration allows the first body region to have a theoretical threshold level higher than that of the second body region.

In a third example of the insulated gate type switching device disclosed herein, a concentration of second conductivity type impurities in the first body region is higher than a concentration of the second conductivity type impurities in the second body region. This configuration allows the first body region to have a theoretical threshold level higher than that of the second body region.

In a fourth example of the insulated gate type switching device disclosed herein, a work function of a portion of the gate electrode facing the first body region is larger than a work function of a portion of the gate electrode facing the second body region. This configuration allows the first body region to have a theoretical threshold level higher than that of the second body region.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. An insulated gate type switching device, comprising:
a first region being of a first conductivity type;
a body region being of a second conductivity type and in contact with the first region;
a second region being of the first conductivity type and separated from the first region by the body region;
an insulating film being in contact with the first region, the body region and the second region; and
a gate electrode facing the body region via the insulating film,
wherein
the body region comprises a first body region and a second body region,
in a region being in contact with the insulating film, the first body region is in contact with the first region and separated from the second region by the second body region,
in the region being in contact with the insulating film, the second body region is in contact with the second region and separated from the first region by the first body region, and
the first body region has a theoretical threshold level Vth larger than that of the second body region,
wherein
Vth=φMS−QB/Cox+2φFB,
where
φMS is a value obtained by subtracting a work function of the body region from a work function of the gate electrode,
Cox is a capacitance per unit area between the body region and the gate electrode,
φFB=kT ln(NA/ni),
k is a Boltzmann constant,
T is a temperature of the body region,
NA is a concentration of impurities in the body region,
ni is a concentration of carriers in an intrinsic semiconductor made of a material of the body region, and
wherein
QB=qNAxd,
where
q is an elementary charge of an electron,
$$xd - {( \frac{4 ɛ kTln ( \frac{NA}{ni} )}{{q}^{2} NA} )}^{\frac{1}{2}} ,$$
and
∈ is a dielectric constant of the material of the insulating film.

2. An insulated gate type switching device, comprising:
a first region being of a first conductivity type;
a body region being of a second conductivity type and in contact with the first region;
a second region being of the first conductivity type and separated from the first region by the body region;
an insulating film being in contact with the first region, the body region and the second region; and
a gate electrode facing the body region via the insulating film,
wherein
the body region comprises a first body region and a second body region,
in a region being in contact with the insulating film, the first body region is in contact with the first region and is separated from the second region by the second body region,
in the region being in contact with the insulating film, the second body region is in contact with the second region and is separated from the first region by the first body region, and
a portion of the insulating film being in contact with the first body region is thicker than a portion of the insulating film being in contact with the second body region.

3. The insulated gate type switching device of claim 2, wherein
the first region is a drain region, and
the second region is a source region.

4. An insulated gate type switching device, comprising:
a first region being of a first conductivity type;
a body region being of a second conductivity type and in contact with the first region;
a second region being of the first conductivity type and separated from the first region by the body region;
an insulating film being in contact with the first region, the body region and the second region; and
a gate electrode facing the body region via the insulating film,
wherein
the body region comprises a first body region and a second body region,
in a region being in contact with the insulating film, the first body region is in contact with the first region and is separated from the second region by the second body region,
in the region being in contact with the insulating film, the second body region is in contact with the second region and is separated from the first region by the first body region, and
a dielectric constant of a portion of the insulating film being in contact with the first body region is smaller than a dielectric constant of a portion of the insulating film being in contact with the second body region.

5. An insulated gate type switching device, comprising:
a first region being of a first conductivity type;
a body region being of a second conductivity type and in contact with the first region;
a second region being of the first conductivity type and separated from the first region by the body region;
an insulating film being in contact with the first region, the body region and the second region; and
a gate electrode facing the body region via the insulating film,
wherein
the body region comprises a first body region and a second body region,
in a region being in contact with the insulating film, the first body region is in contact with the first region and is separated from the second region by the second body region,
in the region being in contact with the insulating film, the second body region is in contact with the second region and is separated from the first region by the first body region, and
a concentration of second conductivity type impurities in the first body region is higher than a concentration of the second conductivity type impurities in the second body region.

6. An insulated gate type switching device, comprising:
a first region being of a first conductivity type;
a body region being of a second conductivity type and in contact with the first region;
a second region being of the first conductivity type and separated from the first region by the body region;
an insulating film being in contact with the first region, the body region and the second region; and
a gate electrode facing the body region via the insulating film,
wherein
the body region comprises a first body region and a second body region,
in a region being in contact with the insulating film, the first body region is in contact with the first region and is separated from the second region by the second body region,
in the region being in contact with the insulating film, the second body region is in contact with the second region and is separated from the first region by the first body region, and
a work function of a portion of the gate electrode facing the first body region is larger than a work function of a portion of the gate electrode facing the second body region.
